(19) United States
(12) Patent Application Publication
(10) Pub. No.: US 2010/0144097 A1
(43) Pub. Date: Jun. 10, 2010

(54) METHOD OF MANUFACTURING SEMICONDUCTOR DEVICE IN WHICH BOTTOM SURFACE AND SIDE SURFACE OF SEMICONDUCTOR SUBSTRATE ARE COVERED WITH RESIN PROTECTIVE FILM

(75) Inventors: TAISUKE KOROKU, SAGAMIHARA-SHI (JP); OSAMU OKADA, HAMURA-SHI (JP); OSAMU KUWABARA, TOKYO (JP); JUNJI SHIOTA, HAMURA-SHI (JP); NOBUMITSU FUJII, OME-SHI (JP)

Correspondence Address: FRISHAUF, HOLTZ, GOODMAN & CHICK, PC, 220 Fifth Avenue, 16TH Floor, NEW YORK, NY, 10001-7708, US

(73) Assignees: CASIO COMPUTER CO., LTD., TOKYO (JP); EPAS

(21) Appl. No.: 12/632,054

(22) Filed: Dec. 7, 2009

(30) Foreign Application Priority Data
Dec. 9, 2008 (JP) 2008-313208

(51) Int. Cl. H01L 21/50; H01L 21/60

(52) U.S. Cl. 438/113; 257/E21.502; 257/E21.508; 257/E21.499

(57) ABSTRACT

First, a trench is formed in parts of a semiconductor wafer, a sealing film and other elements corresponding to a dicing street and both sides thereof. In this state, the semiconductor wafer is separated into silicon substrates by the formation of the trench. Then, a resin protective film is formed on the bottom surface of each silicon substrate including the inner part of the trench. In this case, the semiconductor wafer is separated into the silicon substrates. However, a support plate is affixed to the upper surfaces of the columnar electrode and the sealing film via an adhesive layer. Therefore, when the resin protective film is formed, it is possible to prevent the entire workpiece including the separated silicon substrates from being easily warped.

### CROSS-REFERENCE TO RELATED APPLICATIONS

This application is based upon and claims the benefit of priority from prior Japanese Patent Application No. 2008-313208, filed Dec. 9, 2008, the entire contents of which are incorporated herein by reference.

### BACKGROUND OF THE INVENTION

1. Field of the Invention

The present invention relates to a method of manufacturing a semiconductor device in which the bottom surface and side surface of a semiconductor substrate are covered with a resin protective film.

2. Description of the Related Art

A device which is called a chip-size package (CSP) is known from Published Japanese Patent No. 4103896. In this semiconductor device, a plurality of wiring lines are provided on the upper surface of an insulating film disposed on a semiconductor substrate. A columnar electrode is provided on the upper surface of a connection pad portion of the wiring line. A sealing film is provided on the upper surface of the insulating film including the wiring lines so that the upper surface of this sealing film is flush with the upper surface of the columnar electrode. A solder ball is provided on the upper surface of the columnar electrode. In this case, in order to prevent the exposure of the lower surface and side surface of the semiconductor substrate, the lower surface and side surface of the semiconductor substrate are covered with a resin protective film.

Meanwhile, in Published Japanese Patent No. 4103896, an assembly in which an insulating film, wiring lines, columnar electrodes and a sealing film are formed is prepared on the upper side of a semiconductor substrate in a wafer state (hereinafter referred to as a semiconductor wafer). Then, the semiconductor wafer is inverted. Then, a trench having a predetermined width is formed partway through the sealing film by half-cut (cutting halfway) between semiconductor device formation regions on the bottom side (surface opposite to that on which the sealing film and other elements are formed) of the semiconductor wafer. In this state, the semiconductor wafer is separated into semiconductor substrates by the formation of the trench.

Furthermore, a resin protective film is formed on the bottom surfaces of the semiconductor substrates including the inner part of the trench. Then, the entire workpiece including the semiconductor substrates is inverted. Then, solder balls are formed on the upper surfaces of the columnar electrodes. Then, the sealing film and the resin protective film are cut in the center of the width direction of the trench. Consequently, a semiconductor device having a structure wherein the bottom surface and side surface of the semiconductor substrate are covered with the resin protective film is obtained.

However, in Published Japanese Patent No. 4103896, after the trench is formed partway through the sealing film by half-cut on the bottom side of the inverted semiconductor wafer, the resin protective film is simply formed on the bottom surfaces of the semiconductor substrates including the inner part of the trench. That is, the resin protective film is simply formed in a condition where the semiconductor wafer is separated into the semiconductor substrates by the formation of the trench. Therefore, strength in the half-cut step and the subsequent steps decreases, and the entire workpiece including the semiconductor substrates is warped to a relatively great extent. This disadvantageously causes difficulty in maintaining the quality and in handling in each step.

It is therefore an object of this invention to provide a semiconductor device manufacturing method which can prevent the entire workpiece including semiconductor substrates from being easily warped during the formation of a resin protective film for protecting the semiconductor substrates.

### BRIEF SUMMARY OF THE INVENTION

According to a first aspect of the present invention, there is provided a semiconductor device manufacturing method comprising: preparing an assembly having an insulating film formed on one surface of a semiconductor wafer where an integrated circuit is formed, an interconnect formed on the insulating film in such a manner as to be connected to the integrated circuit, an external connection bump electrode formed on the electrode connection pad portion of the interconnect, and a sealing film formed around the external connection bump electrode; affixing a support plate to the external connection bump electrode and the sealing film via an a separation layer;

forming a trench reaching an intermediate position of the thickness of the sealing film on the bottom side of the semiconductor wafer in parts corresponding to a dicing street and both sides thereof; forming a resin protective film on the bottom surface of the semiconductor wafer including the inner part of the trench; supplying energy from the support plate side onto the separation layer; removing off the support plate from the external connection bump electrode and the sealing film; and cutting the sealing film and the resin protective film in a width smaller than the width of the trench.

According to this invention, a resin protective film is formed on the bottom surface of a semiconductor wafer (semiconductor substrates) including the inner part of a trench in a condition where a support plate is affixed to an external connection bump electrode and a sealing film. Thus, it is possible to prevent the entire workpiece including the semiconductor substrates from being easily warped during the formation of the resin protective film for protecting the semiconductor substrates.

### BRIEF DESCRIPTION OF THE SEVERAL VIEWS OF THE DRAWING

FIG. 1 is a sectional view of one example of a semiconductor device manufactured by a manufacturing method of this invention;

FIG. 2 is a sectional view of an initially prepared assembly in one example of the method of manufacturing the semiconductor device shown in FIG. 1;

FIG. 3 is a sectional view of a step following FIG. 2;

FIG. 4 is a sectional view of a step following FIG. 3;

FIG. 5 is a sectional view of a step following FIG. 4;

FIG. 6 is a sectional view of a step following FIG. 5;

FIG. 7 is a sectional view of a step following FIG. 6;

FIG. 8 is a sectional view of a step following FIG. 7;

FIG. 9 is a sectional view of a step following FIG. 8;

FIG. 10 is a sectional view of a step following FIG. 9;

FIG. 11 is a sectional view of a step following FIG. 10;

FIG. 12 is a sectional view of a step following FIG. 11; and

FIG. 13 is a sectional view of a step following FIG. 12.

### DETAILED DESCRIPTION OF THE INVENTION

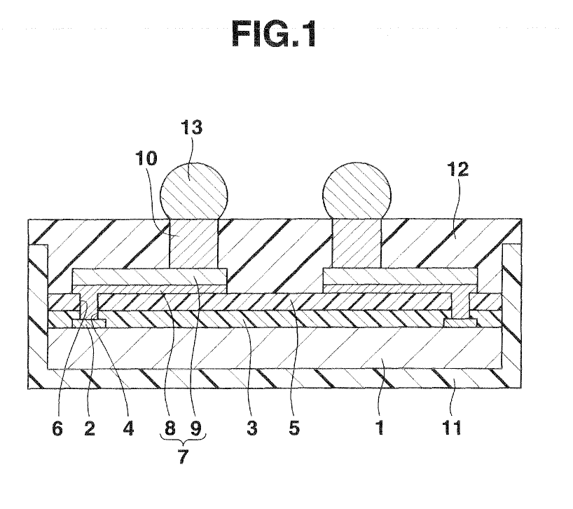

FIG. 1 shows a sectional view of one example of a semiconductor device manufactured by a manufacturing method of this invention. This semiconductor device is generally called a CSP, and includes a silicon substrate (semiconductor substrate) 1. Elements (not shown) constituting an integrated circuit having a predetermined function, such as a transistor, a diode, a register and a condenser, are formed on the upper surface of the silicon substrate 1. Connection pads 2 made of, for example, an aluminum-based metal and connected to the elements of the integrated circuit are provided in the peripheral part of the upper surface of the silicon substrate 1. Although only two connection pads 2 are shown, a large number of connection pads 2 are actually arranged on the peripheral part of the upper surface of the silicon substrate 1.

A passivation film (insulating film) 3 consisting of, for example, silicon oxide is provided on the upper surfaces of the silicon substrate 1 except for the center of the connection pad 2. The center of the connection pad 2 is exposed via an opening 4 provided in the passivation film 3. A protective film (insulating film) 5 consisting of, for example, a polyimide-based resin is provided on the upper surface of the passivation film 3. An opening 6 is provided in a part of the protective film 5 corresponding to the opening 4 of the passivation film 3.

An interconnect 7 is provided on the upper surface of the protective film 5. The interconnect 7 has a two-layer structure composed of a metal foundation layer 8 of, for example, copper provided on the upper surface of the protective film 5, and an upper metal layer 9 of copper provided on the upper surface of the metal foundation layer 8. One end of the interconnect 7 is connected to the connection pad 2 via the passivation film 3 and the protective film openings 4, 6. A columnar electrode (external connection bump electrode) 10 made of copper is provided on the upper surface of a connection pad portion (electrode connection pad portion) of the interconnect 7.

A resin protective film 11 consisting of, for example, epoxy resin is provided on the bottom surface of the silicon substrate 1 and on the side surfaces of the silicon substrate 1, the passivation film 3 and the upper protective film 5. In this case, the upper part of the resin protective film 11 provided on the side surfaces of the silicon substrate 1, the passivation film 3 and the upper protective film 5 projects straight upward from the upper surface of the upper protective film 5. In this state, the lower surface of the silicon substrate 1 and the side surfaces of the silicon substrate 1, the passivation film 3 and the upper protective film 5 are covered with the resin protective film 11.

A sealing film 12 consisting of, for example, epoxy resin is provided on the upper surface of the upper protective film 5 including the interconnect 7 and on the upper surface of the resin protective film 11 therearound. The columnar electrode 10 is provided so that its upper surface is flush with or several μm lower than the upper surface of the sealing film 12. A solder ball 13 is provided on the upper surface of the columnar electrode 10.

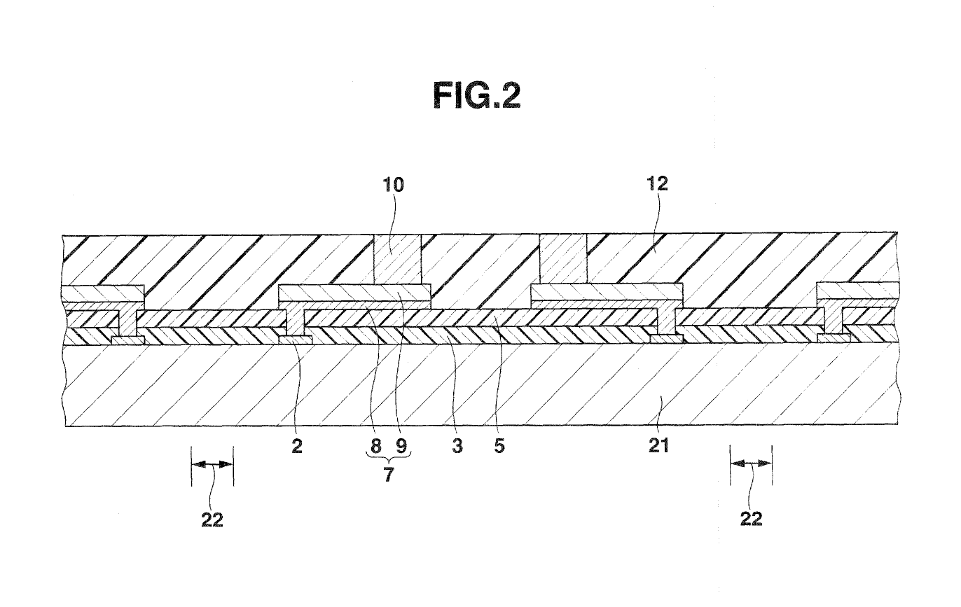

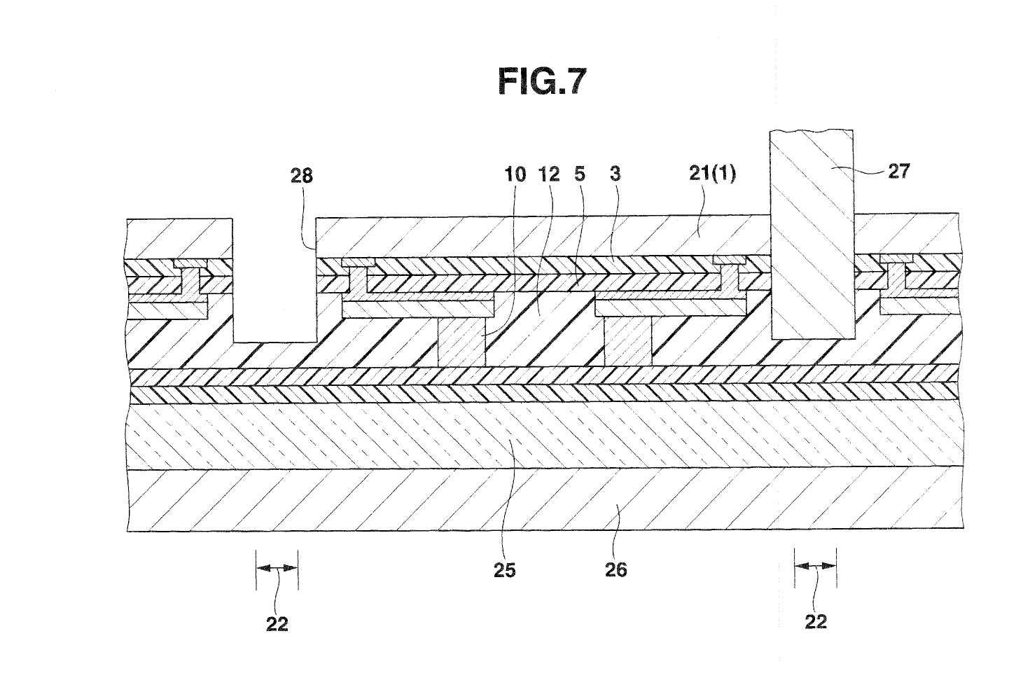

Next, one example of a method of manufacturing this semiconductor device is described. First, as shown in FIG. 2, an assembly in which a connection pad 2, a passivation film 3, a protective film 5, a wiring line 7 having a two-layer structure composed of a metal foundation layer 8 and an upper metal layer 9, a columnar electrode 10 and a sealing film 12 are provided is prepared on a silicon substrate in a wafer state (hereinafter referred to as a semiconductor wafer 21). Such a method of manufacturing the semiconductor wafer 21 is already known. For details, see, for example, FIG. 2 to FIG. 7 and relevant parts in the specification of Japanese Patent No. 3955059.

In this case, the thickness of the semiconductor wafer 21 is greater to some degree than the thickness of the silicon substrate 1 shown in FIG. 1. Moreover, the upper surface of the sealing film 12 including the upper surface of the columnar electrode 10 is planar. Here, a zone indicated by the sign 22 in FIG. 2 is a zone corresponding to the dicing street.

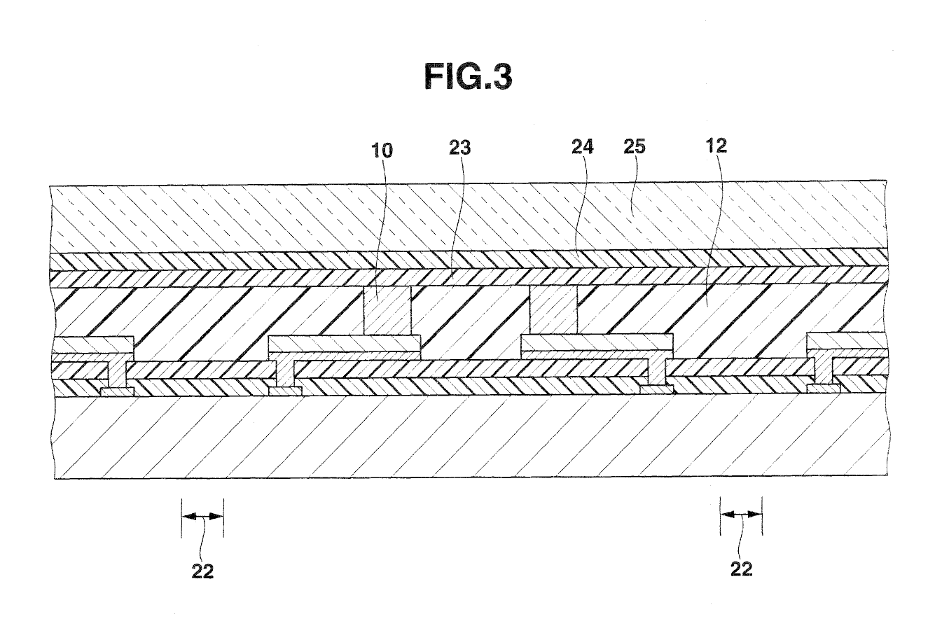

Now, when the assembly shown in FIG. 2 is prepared, a support plate 25 is then affixed to the upper surfaces of the columnar electrode 10 and the sealing film 12 via an adhesive layer 23 and a Separation layer 24, as shown in FIG. 3. In this case, the adhesive layer 23 consists of an ultraviolet-curable adhesive agent. The Separation layer 24 consists of a photothermally convertible material including a light absorbing agent such as carbon black and a thermally decomposable resin (e.g., a wafer support system manufactured by Sumitomo 3M Ltd.). The support plate 25 is a hard plate having the property of transmitting ultraviolet rays, such as a circular glass plate, which is slightly larger than the semiconductor wafer 21.

Furthermore, a liquid adhesive agent for forming the adhesive layer 23 on the upper surfaces of the columnar electrode 10 and the sealing film 12 is first applied by, for example, the spin coating method. On the other hand, the separation layer 24 is previously formed on the lower surface of the support plate 25 made of glass. Then, the separation layer 24 previously formed on the lower surface of the support plate 25 is affixed to the upper surface of the applied liquid adhesive agent under vacuum. This affixing is carried out under vacuum to prevent air from being contained between the separation layer 24 previously formed on the lower surface of the support plate 25 and the adhesive layer 23. Then, ultraviolet rays are radiated from the side of the support plate 25, and the applied liquid adhesive agent is cured to form the adhesive layer 23. In addition, the separation layer 24 is not thermally decomposed by the low-energy ultraviolet radiation.

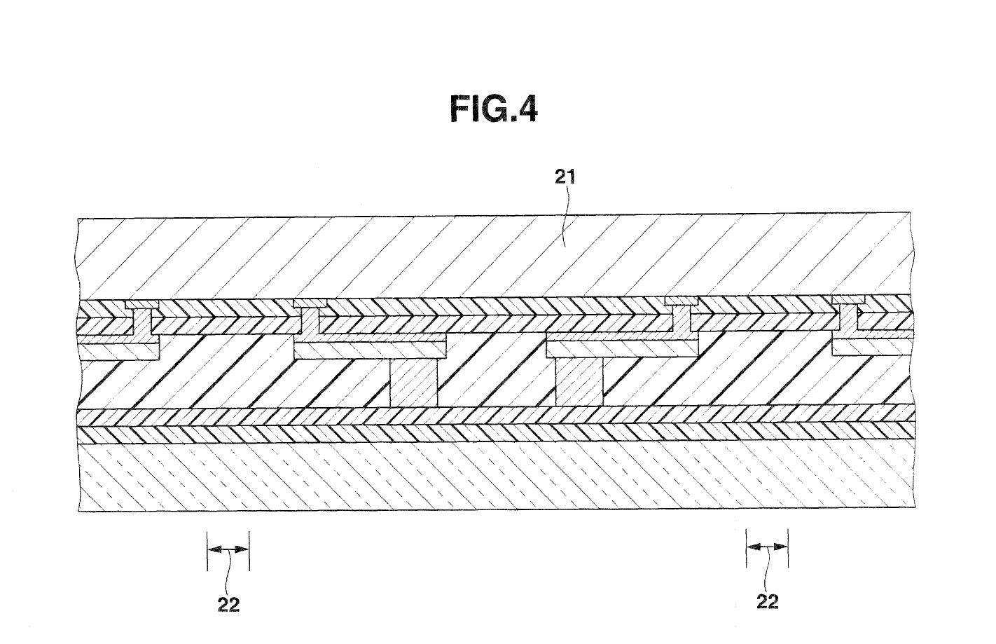

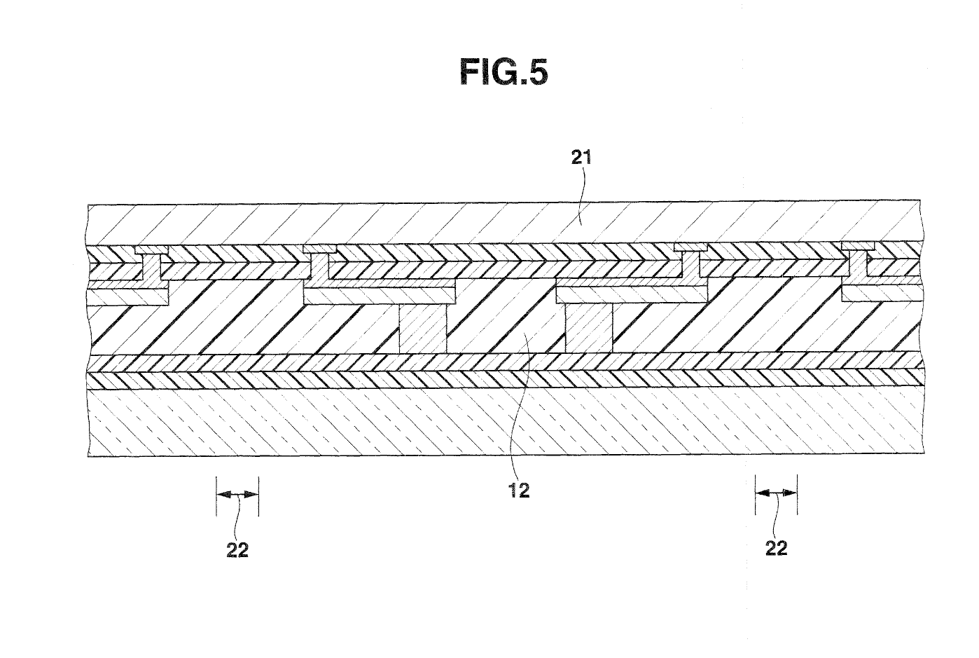

Then, the assembly shown in FIG. 3 is inverted to turn up the bottom surface (surface opposite to that on which the sealing film 12 and other elements are formed) of the semiconductor wafer 21, as shown in FIG. 4. Then, as shown in FIG. 5, the bottom side of the semiconductor wafer 21 is properly ground using a grindstone (not shown) to properly reduce the thickness of the semiconductor wafer 21. In addition, the support plate 25 including the separation layer 24 may be affixed after the thickness of the semiconductor wafer 21 is properly reduced.

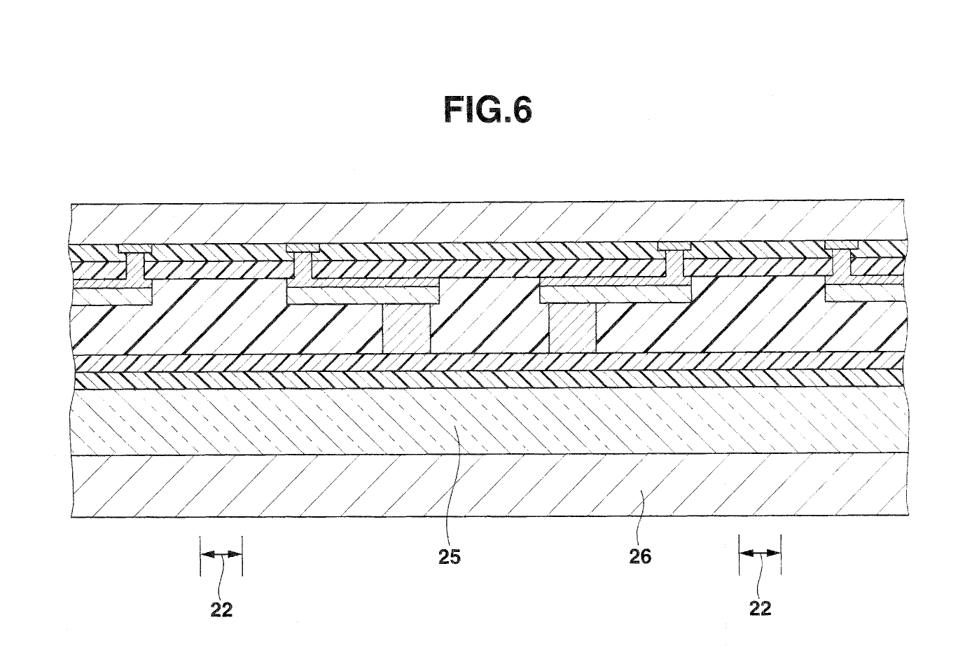

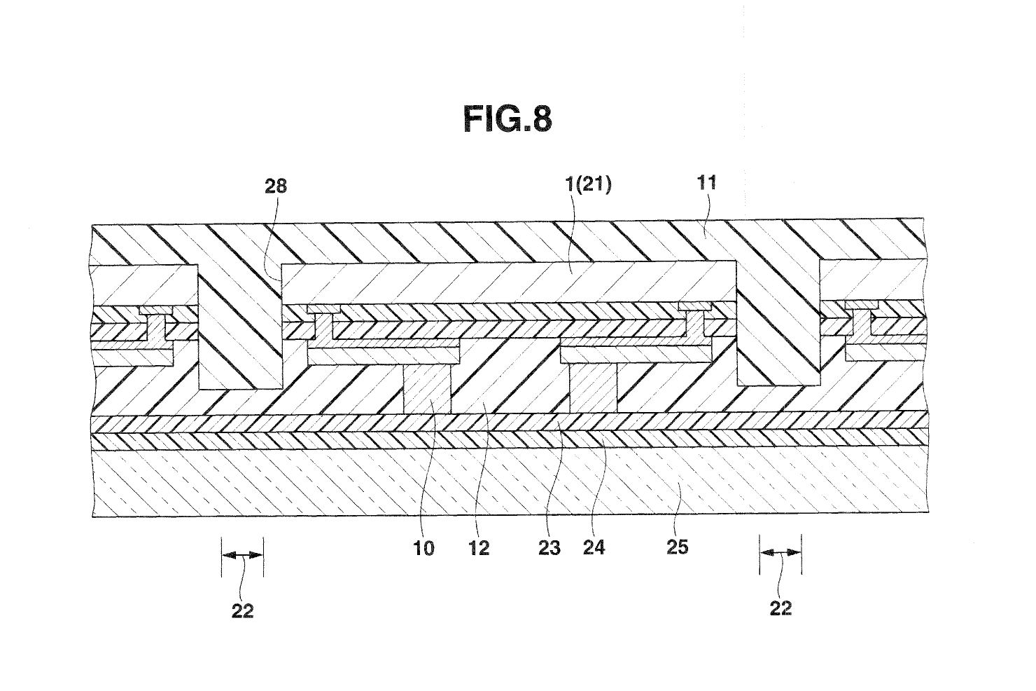

Then, as shown in FIG. 6, the lower surface of the support plate 25 is affixed to the upper surface of a dicing tape 26. Then, as shown in FIG. 8, a blade 27 is prepared. This blade 27 is a disk shaped grindstone. The sectional shape of its edge is substantially U-shaped, and its thickness is greater to some degree than the width of the dicing street 22.

Furthermore, this blade 27 is used to form a trench 28 in parts of the semiconductor wafer 21 corresponding to the dicing street 22 and both sides thereof, the passivation film 3, the protective film 5 and the sealing film 12. In this case, the depth of the trench 28 extends partway in the sealing film 12, and is, for example, ½ or more, preferably ⅓ or more than the thickness of the sealing film 12. In this state, the semiconductor wafer 21 is separated into the semiconductor substrates 1 by the formation of the trench 28. Then, the support plate 25 is detached from the upper surface of the dicing tape 26. In addition, in this step, the use of a dicing machine for the half-cut enables processing without affixing the dicing tape.

Then, as shown in FIG. 8, a thermosetting resin such as epoxy resin is applied to the bottom side of the silicon substrate 1 including the inner part of the trench 28 by, for example, the spin coating or screen printing method. The thermosetting resin is cured to form the resin protective film 11. The curing temperature of the resin protective film 11 ranges between 150 and 250° C. in consideration of the thermal resistance of the adhesive layer 23 and the separation layer 24, and the processing time is about one hour.

In this case, the semiconductor wafer 21 is separated into the silicon substrates 1. However, the support plate 25 is affixed to the lower surfaces of the columnar electrode 10 and the sealing film 12 via the adhesive layer 23 and the separation layer 24. Therefore, when the resin protective film 11 consisting of a thermosetting resin such as epoxy resin is applied and cured, it is possible to prevent the entire workpiece including the separated silicon substrates 1 from being easily warped, and it is also possible to prevent any difficulty from being caused in the subsequent steps by the warping.

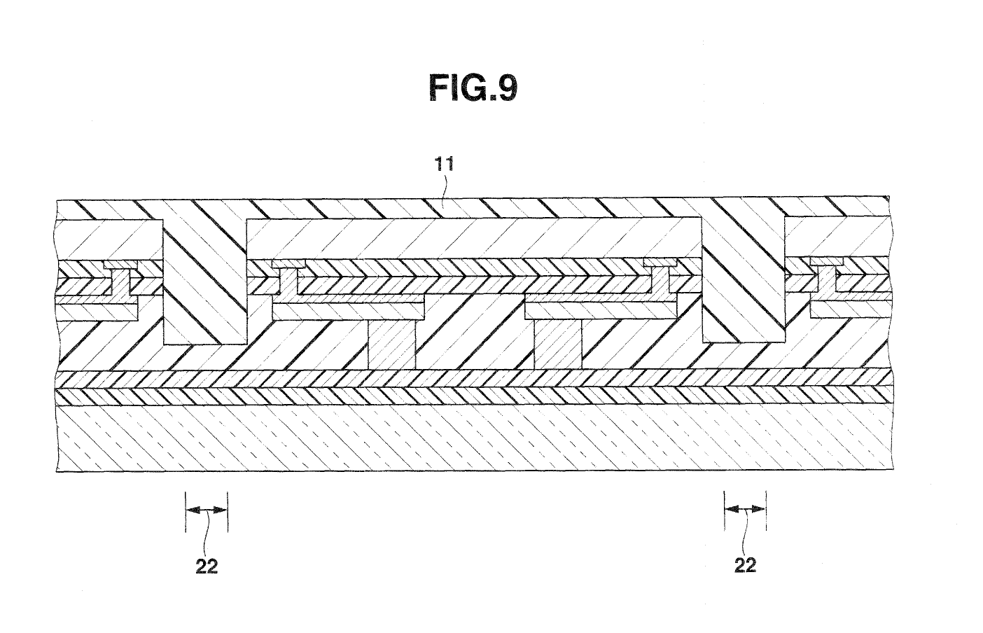

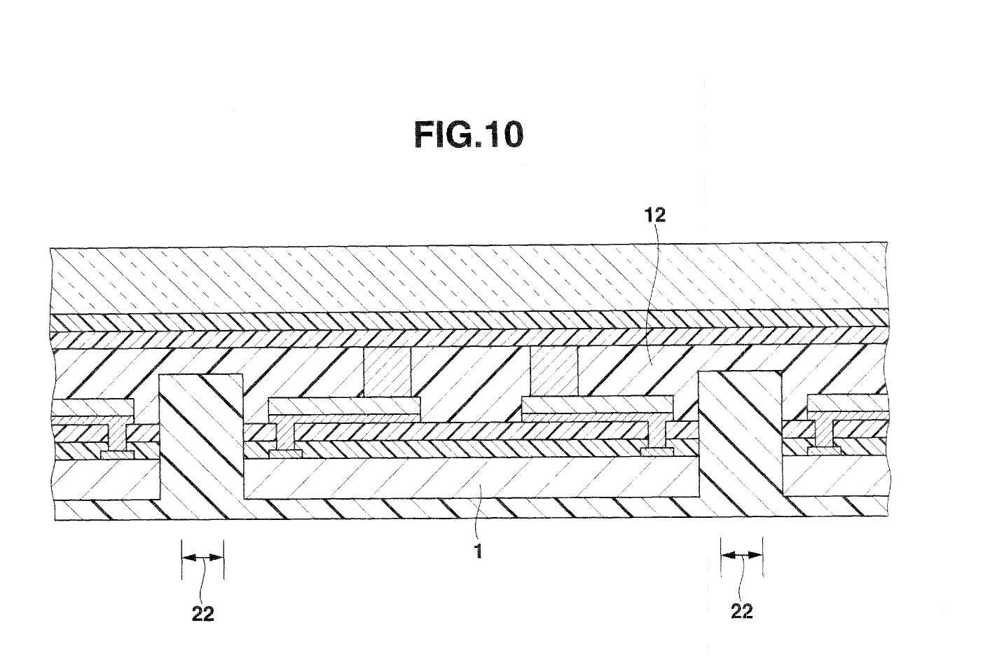

Then, as shown in FIG. 9, the upper side of the resin protective film 11 is properly ground using a grindstone (not shown) to properly reduce the thickness of the resin protective film 11 and to planarize the upper surface of the resin protective film 11. This grinding step is performed to further reduce the thickness of the semiconductor device. Then, the assembly shown in FIG. 9 is inverted to turn up the side of the silicon substrate 1 where the sealing film 12 and other elements are formed, as shown in FIG. 10.

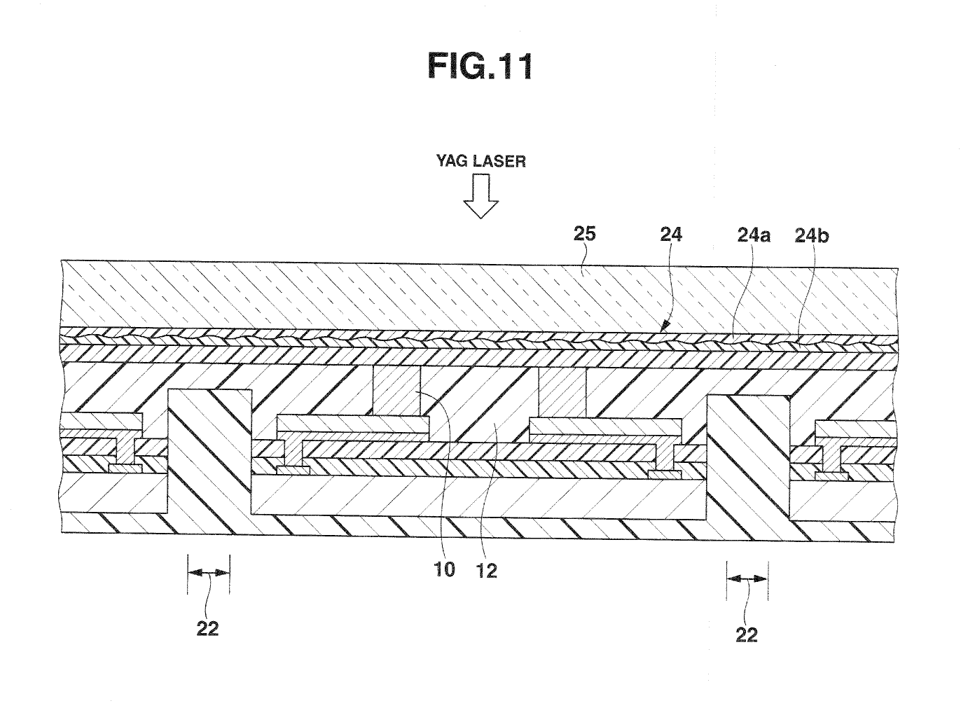

Then, as shown in FIG. 11, the light of a yttrium aluminum garnet (YAG) laser light is radiated from the upper side of the support plate 25. Thus, the energy of the YAG laser light is absorbed by the light absorbing agent of the separation layer 24, and converted into thermal energy. The thermal energy produced by the conversion thermally decomposes the thermally decomposable resin of the separation layer 24, and a gas is generated by the thermal decomposition. An air gap is formed in the separation layer 24 by the generated gas, and the separation layer 24 self-separates in its thickness direction, that is, the separation layer 24 self-separates into an upper separation layer 24a and a lower separation layer 24b. The thermally decomposable layer of the photothermally convertible type is disclosed in, for example, Jpn. Pat. Appln. KOKAI Publication No. 2004-64040.

The irradiated light is not limited to the YAG laser light. The infrared rays light or other light is acceptable. Moreover, the separation layer 24 may not be the absorption of light and conversion into the thermal energy. It only has to be the one that is formed the gap with the addition of some energy in the separation layer 24, and is self-separated in the thickness direction.

Then, the support plate 25 is detached from the upper surface of the lower separation layer 24b together with the upper separation layer 24a. Further, the adhesive layer 23 is detached from the upper surfaces of the columnar electrode 10 and the sealing film 12 together with the lower separation layer 24b.

Here, the reason that the separation layer 24 is used in addition to the adhesive layer 23 is described. The support plate 25 made of, for example, glass is riot flexible, so that its region corresponding to the whole surface of the semiconductor wafer has to be detached at once. In other words, the support plate 25 can not be peeled off little by little. Therefore, it is riot possible to separate the support plate 25 and the silicon substrate 1 from each other without deformation or damage. Thus, the separation layer 24 is used to facilitate the detachment of the support plate 25. On the other hand, the adhesive layer 23 including the lower separation layer 24b is sufficiently flexible and can therefore be easily peeled off.

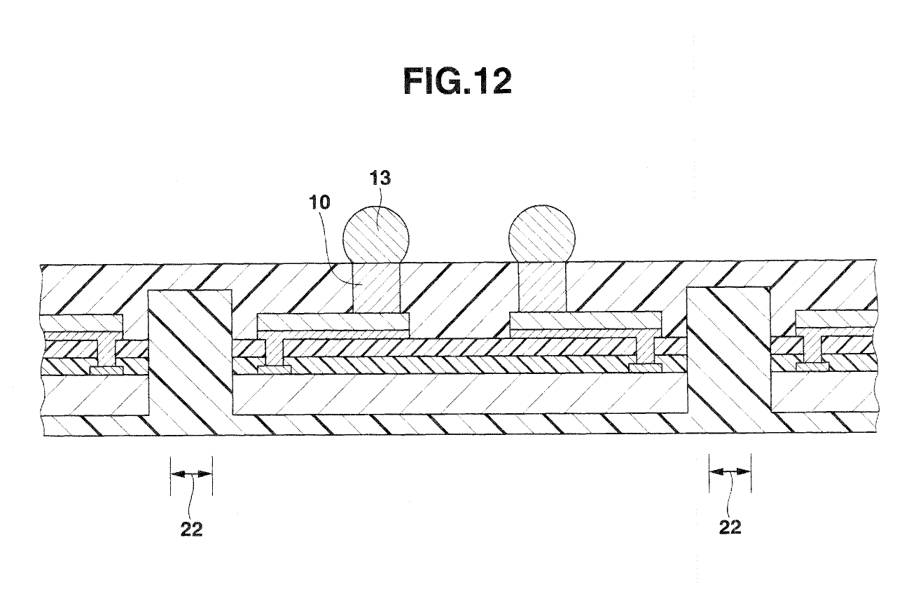

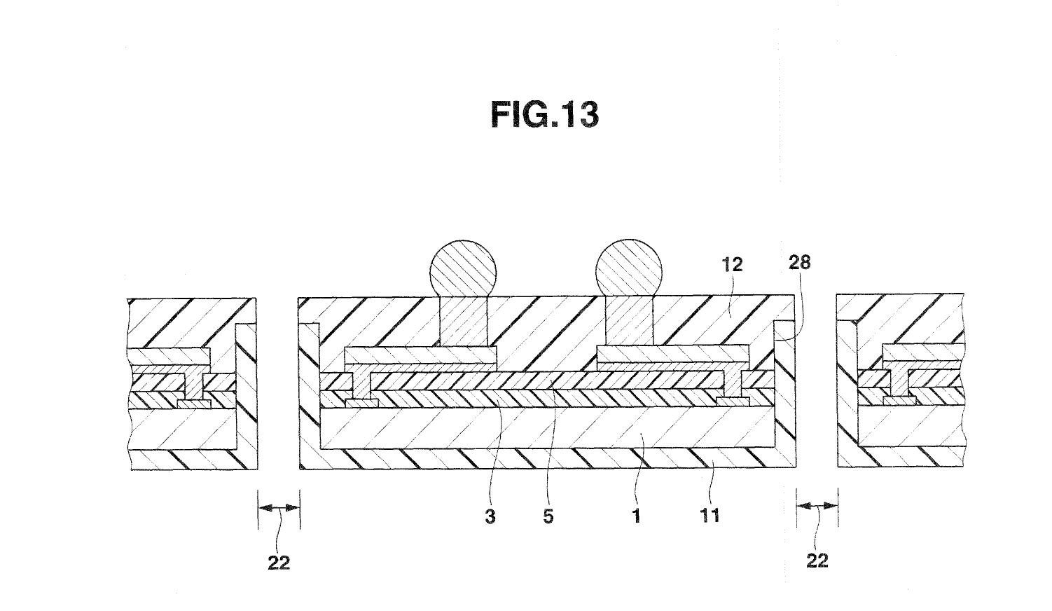

Then, as shown in FIG. 12, a solder ball 13 is formed on the upper surface of the columnar electrode 10. In this case, if a burr and an oxide film are formed on the upper surface of the columnar electrode 10, the upper surface of the columnar electrode 10 is etched several μm to remove the burr and oxide film. Then, as shown in FIG. 13, the sealing film 12 and the resin protective film 11 are cut along the dicing street 22 in the center of the trench 28.

In this case, a blade having the same width as the width of the dicing street 22 is used. Therefore, as shown in FIG. 13, the sealing film 12 is cut so that its side surface is formed to extend from the intermediate position of the resin protective film 11 which is provided on the side surfaces of the silicon substrate 1, the passivation film 3, the protective film 5 and the sealing film 12 up to the intermediate position of the sealing film 12. Consequently, as shown in FIG. 1, a plurality of semiconductor devices having a structure wherein the bottom surface and side surface of the silicon substrate 1 are covered with the resin protective film 11 are obtained.

What is claimed is:

1. A semiconductor device manufacturing method comprising:
preparing an assembly having an insulating film formed on one surface of a semiconductor wafer where an integrated circuit is formed, an interconnect formed on the insulating film in such a manner as to be connected to the integrated circuit, an external connection bump electrode formed on the electrode connection pad portion of the interconnect, and a sealing film formed around the external connection bump electrode;
affixing a support plate to the external connection bump electrode and the sealing film via an a separation layer;
forming a trench reaching an intermediate position of the thickness of the sealing film on the bottom side of the semiconductor wafer in parts corresponding to a dicing street and both sides thereof;
forming a resin protective film on the bottom surface of the semiconductor wafer including the inner part of the trench;
supplying energy from the support plate side onto the separation layer;
removing off the support plate from the external connection bump electrode and the sealing film; and
cutting the sealing film and the resin protective film in a width smaller than the width of the trench.

2. The semiconductor device manufacturing method according to claim 1, the separation layer is a light to heat conversion type including the light absorbing agent and a resin.

3. The semiconductor device manufacturing method according to claim 1, the energy is infrared rays light.

4. The semiconductor device manufacturing method according to claim 1, further comprising forming an adhesive layer between the external connection bump electrode as well as the sealing film and the separation layer.

5. The semiconductor device manufacturing method according to claim 4, wherein affixing the support plate includes applying an ultraviolet-curable liquid adhesive agent to the external connection bump electrode and the sealing film, previously forming the separation layer on one surface of the support plate, affixing, to the liquid adhesive agent, the separation layer previously formed on one surface of the support plate, and radiating ultraviolet rays to cure the liquid adhesive agent and thereby forming the adhesive layer.

6. The semiconductor device manufacturing method according to claim 5, wherein affixing, to the liquid adhesive agent, the separation layer previously formed on one surface of the support plate is carried out under vacuum.

7. The semiconductor device manufacturing method according to claim 5, wherein the support plate is made of glass.

8. The semiconductor device manufacturing method according to claim 1, further comprising grinding the bottom side of the semiconductor wafer to reduce the thickness of the semiconductor wafer after or before the support plate is affixed.

9. The semiconductor device manufacturing method according to claim 1, further comprising grinding the upper side of the resin protective film to reduce the thickness of the resin protective film and planarize the upper surface of the resin protective film, after the resin protective film is formed.

10. The semiconductor device manufacturing method according to claim 1, wherein the external connection bump electrode is a columnar electrode formed on the electrode connection pad portion.

11. The semiconductor device manufacturing method according to claim 10, further comprising forming a solder ball on the columnar electrode after the resin protective film is formed.
